(19) United States
(12) Patent Application Publication
(10) Pub. No.: US 2007/0018708 A1
(43) Pub. Date: Jan. 25, 2007

(54) Method and apparatus for determining optimal delay time and computer-readable storage medium storing optimal delay time determining program

(75) Inventor: Dong-hyun Yoo, Seoul (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/438,224

(22) Filed: May 23, 2006

(30) Foreign Application Priority Data
Jul. 1, 2005 (KR) 2005-59183

(51) Int. Cl. H03H 11/26

(52) U.S. Cl. 327/261

(57) ABSTRACT

A method of and an apparatus for determining an optimal delay time and a computer-readable storage medium storing an optimal delay time determining program. By determining an optimal delay time between data packet transmissions from a master to a slave through a serial data line, speed reduction and overload of a master/slave system is preventable. A data packet is transmitted from the master to the slave through the serial data line and the master judges whether the transmitted data packet is received within a predetermined delay time based on an acknowledge signal received from the slave. If the acknowledge signal is not received by the master within the predetermined delay time, the master increases the delay time by an increment and re-transmits the data packet. The incrementing, transmitting and judging are repeated until an optimal delay time is determined.

### CROSS-REFERENCE TO RELATED APPLICATIONS

This application claims the benefit of Korean Patent Application No. 2005-59183, filed Jul. 1, 2005, in the Korean Intellectual Property Office, the disclosure of which is incorporated herein by reference.

### BACKGROUND OF THE INVENTION

1. Field of the Invention

Aspects of the present invention relate in general to a method of and an apparatus for determining an optimal delay time between data packet transmissions and a computer-readable storage medium storing an optimal delay time determining program. More specifically, the aspects of the present invention relate to a method of and an apparatus for determining an optimal delay time between data packet transmissions from a master to a slave through a serial data line, thereby preventing a speed reduction and an overload of a master/slave system, and a computer-readable storage medium storing an optimal delay time determining program.

2. Description of the Related Art

FIG. 1 is a diagram showing a delay time between data packet transmissions from a master to a slave through a serial data line. An Inter-integrated Circuit (IIC) bus may be used for a communication between the master and the slave. The IIC bus is a bi-directional two-wire serial bus that provides a synchronized communication between the master and the slave using a serial clock (SCL) line and a serial data (SDA) line for data transmission.

The master transmits data to the slave. For example, a microcontroller may be used as the master, and an electrically erasable and programmable read only memory (EEPROM) may be used as the slave. The EEPROM is a special type of PROM that may be erased or rewritten by exposing the EEPROM to an electrical charge. Since the EEPROM is electrically readable and electrically re-writable, the EEPROM may be programmed while installed in a system.

If the master transmits data, which may be in a form of a data packet, to the slave and the slave receives the data well, an acknowledge (ACK) signal indicating that the data has been well received is usually sent to the master. The terms data and data packet will be used interchangeably in the following description.

A drawback of IIC bus protocol is that the slave cannot receive subsequent data transmitted from the master if the slave is currently engaged in storing previously transmitted data. Thus, the slave does not transmit an ACK signal for the subsequent data to the master. For this reason, the master should not transmit any subsequent data to the slave unless the master gives a sufficient time to the slave for receiving and processing the previous data. The time interval for data transmission between the master and the slave is called a delay time.

The delay time is defined by the attributes of the slave. For example, each EEPROM has a write cycle timing, which is a time required for storing received data, defined in a specification of the EEPROM. The delay time is set in consideration of the write cycle timing of the slave.

Conventionally, the master fixes a delay time for every product, and transmits data to the slave after the fixed delay time. The problems of using the fixed delay time are that data transmission rate between the master and the slave is reduced and an overload occurs. More details regarding fixed time delay transmission are provided with reference to FIG. 2.

FIG. 2 is a flow chart explaining a method of transmitting a data packet from a master to a slave through a serial data line after a fixed delay time, according to the related art. In operation S100, the master transmits a first data packet to the slave after a predetermined delay time. Then, in operation S110, the master judges whether an ACK signal, indicating that the slave has received the first data packet well, is received from the slave. If the master receives the ACK signal (S110:Y), it is judged that the data packet transmission has been successful. Thus, the master transmits a subsequent data packet to the slave after another fixed delay time.

However, if the master does not receive the ACK signal from the slave (S110:N), the master returns to operation 100 and transmits the first data packet again. That is, the master transmits the first data packet again after the predetermined fixed delay time. When repeated transmissions occur, the transmission rate of a master/slave system is reduced. Moreover, where the predetermined fixed delay time is set too short, the transmission rate of the system is lowered even more severely because the master keeps transmitting data until the master receives the ACK signal. On the contrary, where the delay time is set too long, an overload occurs to the master/slave system because there is too much delay time.

### SUMMARY OF THE INVENTION

An aspect of the present invention provides a method of and an apparatus for determining an optimal delay time between data packet transmissions from a master to a slave through a serial data line, thereby preventing a speed reduction of data transmission and an overload of a master/slave system. Another aspect of the present invention provides a computer-readable storage medium storing an optimal delay time determining program.

To achieve the above and/or other aspects and/or advantages, a method of determining an optimal delay time between data packet transmissions from a master to a slave through a serial data line includes: transmitting a data packet to the slave after a predetermined delay time; judging whether the transmitted data packet is received; increasing the delay time by a predetermined increment of time and repeating the transmitting of the data packet and the judging of whether the data packet is received, if the judging judges that the data packet is not received; and determining the increased delay time as an optimal delay time between data packet transmissions from the master to the slave, if the judging judges that the data packet is received.

The slave may be a storable memory, and the predetermined delay time is initialized to a value smaller than a write cycle timing of the memory. The memory may be an Electrically Erasable and Programmable Read Only Memory (EEPROM) and the serial data line may be an Inter-integrated Circuit (IIC) bus data line.

Another aspect of the present invention provides an apparatus for determining an optimal delay time between data packet transmissions from a master to a slave through a serial data line, the apparatus including: a transmission unit transmitting a data packet to the slave after a predetermined delay time; a judgment unit judging whether the transmitted data packet is received; and a determination unit increasing the delay time by a predetermined increment of time if the judgment unit judges that the data packet is not received by the slave and determining the delay time as an optimal delay time between data packet transmissions from the master to the slave if the judgment unit judges that the data packet is received by the slave.

The slave may be a storable memory, and the predetermined delay time may be initialized to a value smaller than a write cycle timing of the memory. The memory may be an EEPROM and the serial data line may be an IIC bus data line.

Another aspect of the present invention provides a computer-readable storage medium storing an optimal delay time determining program, capable of instructing a processor to execute: transmitting a data packet from a master to a slave through a serial data line after a predetermined delay time; judging whether the transmitted data packet is received; increasing the delay time by a predetermined increment of time, and repeating the transmitting of the data packet and the judging of whether the data packet is received, if the data packet is not received, and determining the delay time as an optimal delay time between data packet transmissions from the master to the slave, if the data packet is received.

The slave may be a storable memory, and the predetermined delay time may be initialized to a value smaller than a write cycle timing of the memory. The memory may be an EEPROM and the serial data line may be an IIC bus data line.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a flow chart explaining a delay time between data packet transmissions from a master to a slave through a serial data line;

FIG. 2 is a flow chart explaining a method of transmitting a data packet from a master to a slave through a serial data line after a fixed delay time, according to the related art.

FIG. 3 is a flow chart explaining a method of determining an optimal delay time between data packet transmissions, according to an embodiment of the present invention;

FIGS. 4A-4D are diagrams showing a procedure for determining an optimal delay time between data packet transmissions, according to an embodiment of the present invention; and

FIG. 5 is a functional block diagram of an apparatus capable of determining an optimal delay time, according to an embodiment of the present invention.

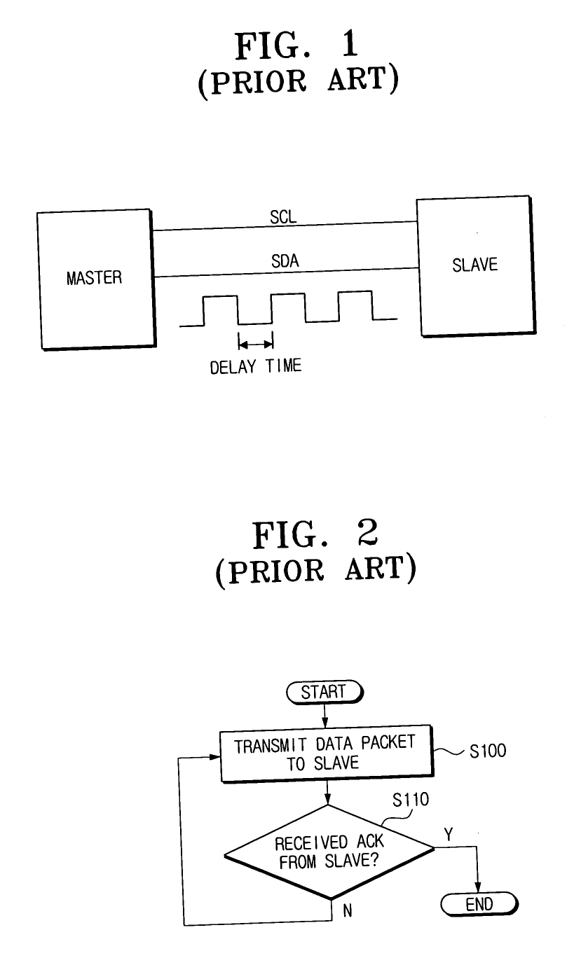

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

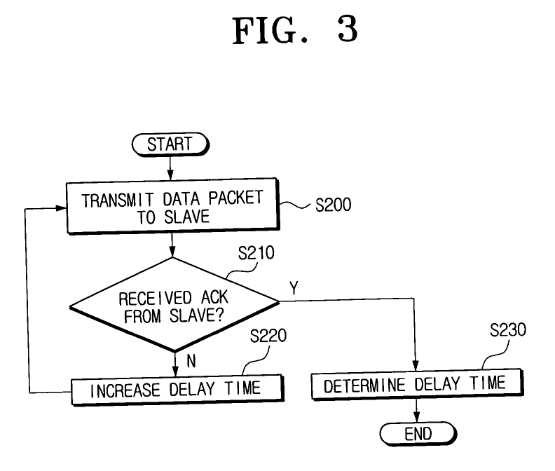

FIG. 3 is a flow chart explaining a method of determining an optimal delay time between data packet transmissions, according to an embodiment of the present invention. A master transmits a data packet to a slave after a predetermined delay time at operation S200. Desirably, the delay time is initialized (“initialized delay time”) to as small as possible in consideration of expected properties of the slave. For instance, if an EEPROM is a slave, the initialized delay time is much smaller than a defined write cycle timing of the EEPROM. Here, the data packet refers to data being transmitted on the basis of a predetermined delay time unit.

A slave, an EEPROM for example, has a write cycle timing, which corresponds to the time required for storing the received data, as defined in a specification for the EEPROM. Generally, a smaller time value than the write cycle timing is used as the delay time. Because of variations in chip properties, the amount of time required is unspecified. Nevertheless, if the delay time is uniformly set to a smaller time value than the write cycle timing, the speed reduction or overload occurs to the master/slave system. Therefore, it is important to find an optimal delay time in consideration of variable chip properties. The method of determining an optimal delay time according to an embodiment of the present invention provides that the delay time is initialized at a smaller time value than the write cycle timing and then subsequently increased.

With continued reference to FIG. 3, the master judges at operation S210 whether the data packet transmitted in operation S200 has been received well. The master makes such judgment based on whether an ACK signal is received from the slave. Where an IIC bus protocol is used for storing data in the slave, the data packet includes information on the address of the slave, information on the address where the data is stored, and the data to be stored; and the master receives an ACK signal, respectively, every time the information on the address of the slave, the information on the address where the data is stored, and the data to be stored are transmitted. If the master does not receive any of the respective ACK signals, the master concludes that the transmitted data packet has not been received properly by the slave.

The initialized delay time is increased by a predetermined increment at operation 220 if the master does not receive the ACK signal at operation S210. The initialized delay time is increased because the master may not receive the ACK signal again if the initialized delay time is used without change. Here, the increment may be adequately set without going through too many incremental changes. However, if the increment is too small it may take longer to determine an optimal delay time. On the other hand, if the increment is too large an optimal delay time may not be found. If the master does not receive the ACK signal at operation S210, the operations S220, S200 and S210 are repeated.

Meanwhile, if the master receives the ACK signal at operation S210, the delay time used for receiving the ACK signal is set to the delay time between data packet transmissions from the master to the slave through a serial data line at operation S230.

In other words, the delay time set in operation S230 is regarded as an optimal delay time between data packet transmissions from the master to the slave through a serial data line. Thus, the master transmits a subsequent data packet to the slave after the delay time set in operation S230.

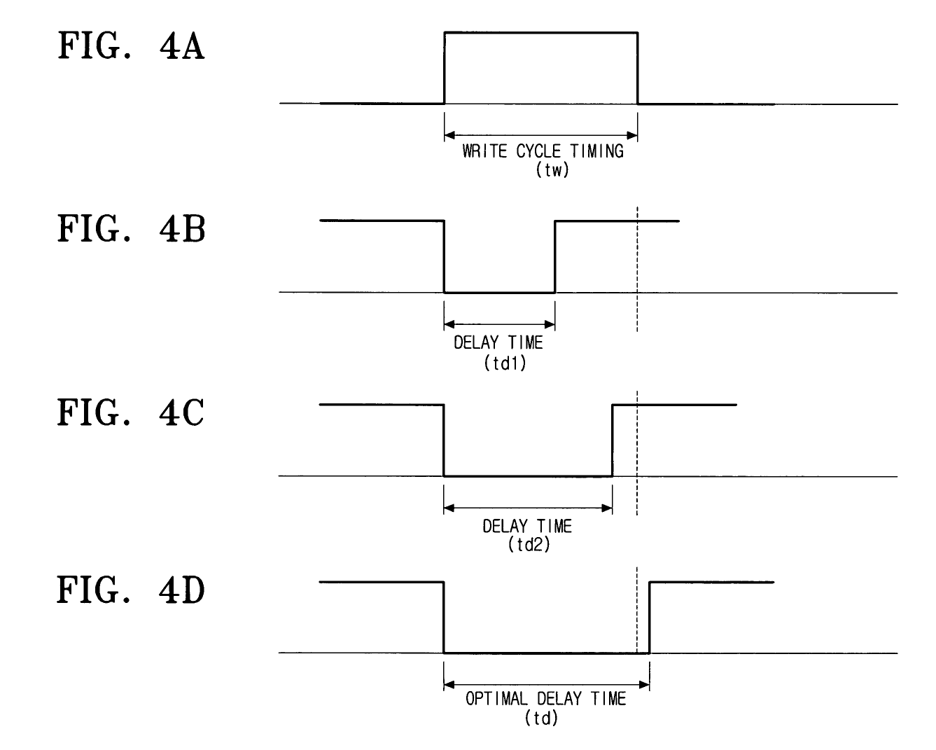

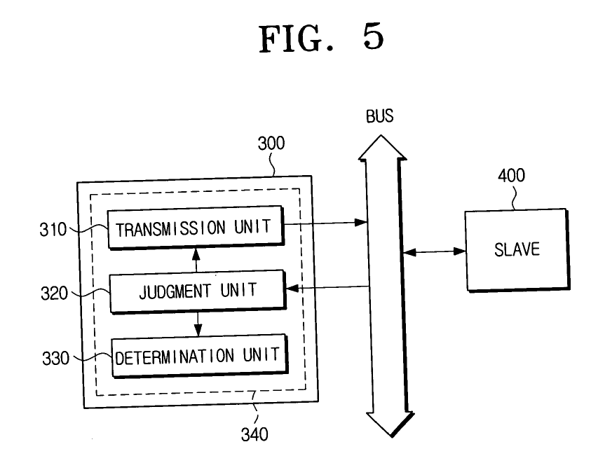

FIGS. 4A, 4B, 4C and 4D are diagrams illustrating an example of the method of determining an optimal delay time between data packet transmissions, according to the embodiment of the present invention shown in FIG. 3. The example will be shown diagrammatically in terms of a delay time with respect to a write cycle timing tw in FIG. 4A, provided that a slave is a recordable memory, e.g., an EEPROM. Also, the example will be described referring to the flow chart described with respect to FIG. 3.

Initially, a master transmits a data packet to a slave after a delay time td1 shown in FIG. 4B at operation 200. In some case, the master may not receive an ACK signal from the slave for the transmitted data packet (S210:N). Failure to receive the ACK signal may occur because the write cycle timing tw of the slave is greater than the delay time td1.

Next, the master transmits the data packet after a delay time td2 shown in FIG. 4C, which is longer than the delay time td1 by a predetermined increment (S220 and S200). But still, the master does not receive an ACK signal at operation S210 because the write cycle timing tw of the slave is greater than the delay time td2.

Again, the master transmits the data packet after a delay time td shown in FIG. 4D, which is longer than the delay time td2 by a predetermined increment (S220 and S200). This time the master receives an ACK signal (S210:Y) since the delay time td is slightly longer than the write cycle timing tw of the slave. Therefore, the delay time td of FIG. 4D is selected as an optimal delay time (S230).

In the example shown in FIGS. 4A-4D, the delay time has been changed twice. However, the number of changes can be increased by setting the increment of time very small. As the operations S220, S200 and S210 are repeated, a more optimal delay time is obtained.

The above-described method of determining an optimal delay time between data packet transmissions may be embodied in a computer-readable storage medium, such as, a CD-ROM, a magnetic disk, etc.

FIG. 5 is a functional block diagram of an apparatus for determining an optimal delay time, according to an embodiment of the present invention. The apparatus 340 for determining an optimal delay time may be incorporated as part of the master 300, and includes a transmission unit 310, a judgment unit 320, and a determination unit 330.

The transmission unit 310 transmits a data packet to a slave after an initialized delay time. The initialized delay time is a predetermined minimum value. Where an IIC bus protocol is used to record data in the slave 400, information on the address of the slave 400, information on the address where the data is stored, and data to be stored are contained in the transmitted data packet.

The judgment unit 320 judges whether the data packet transmitted by the transmission unit is received well. The judgment unit 320 makes such judgment based on whether an ACK signal indicating the reception of the data packet is received from the slave 400. Where data is stored in the slave using the IIC bus protocol, the transmission unit 310 receives an ACK signal, respectively, every time the information on the address of the slave, the information on the address where the data is stored, and the data to be stored are transmitted. If the transmission unit 310 fails to receive any of the respective ACK signals, the judgment unit 320 judges that the slave 400 has not received the data packet.

When the judgment unit 320 concludes that the slave has not received the data packet well, the transmission unit 310 increases the initialized delay time by a predetermined increment and transmits the data packet again to the slave.

On the other hand, if the judgment unit 320 concludes that the slave has successfully received the data packet, the determination unit 330 determines or selects the delay time that was applied to the time of receiving the ACK signal as an optimal delay time between data packet transmissions from the master to the slave through a serial data line.

For the subsequent data packet transmissions, the delay time selected by the determination unit 330 is applied.

As explained so far, the method and apparatus for determining the optimal delay time and the computer-readable storage medium storing an optimal delay time determining program of the present invention may be advantageously used for determining an optimal delay time, whereby the speed reduction and overload of the master/slave system is prevented.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of determining an optimal delay time between data packet transmissions from a master to a slave through a serial data line, the method comprising:
transmitting a data packet to the slave after a predetermined delay time;
judging whether the transmitted data packet is received by the slave;
increasing the delay time by a predetermined increment of time and repeating the transmitting of the data packet and the judging of whether the data packet is received, if the judging determines that the data packet is not received; and
determining the delay time as an optimal delay time between data packet transmissions from the master to the slave, if the judging determines that the data packet is received.

2. The method of claim 1, wherein:
the slave is a storable memory, and
the method further comprises initializing the predetermined delay time to a value smaller than a write cycle timing of the memory.

3. The method of claim 2, wherein the memory is an Electrically Erasable and Programmable Read Only Memory (EEPROM).

4. The method of claim 1, wherein the serial data line is an inter-integrated circuit (IIC) bus data line.

5. An apparatus for determining an optimal delay time between data packet transmissions from a master to a slave through a serial data line, the apparatus comprising:
a transmission unit transmitting a data packet to the slave after a predetermined delay time;
a judgment unit judging whether the transmitted data packet is received; and
a determination unit increasing the delay time by a predetermined increment of time, if the judging determines that the data packet is not received, and determining the delay time as an optimal delay time between data packet transmissions from the master to the slave if the judgment unit determines that the data packet is received.

6. The apparatus of claim 5, wherein:
the transmitting unit re-transmits the data packet, if the judging determines that the data packet is not received;
the judgment unit judges whether the re-transmitted data packet is received; and
the determination unit increases the delay time by another predetermined increment of time, if the judging determines that the re-transmitted data packet is not received, and determines the delay time increased by the predetermined increment as an optimal delay time between data packet transmissions from the master to the slave, if the judgment unit determines that the data packet is received within the delay time increased by the predetermined increment.

7. The apparatus of claim 5, wherein:
the slave is a storable memory, and
the predetermined delay time is initialized to a value smaller than a write cycle timing of the memory.

8. The apparatus of claim 7, wherein the memory is an Electrically Erasable and Programmable Read Only Memory (EEPROM).

9. The apparatus of claim 5, wherein the serial data line is an inter-integrated circuit (IIC) bus data line.

10. A computer-readable storage medium storing an optimal delay time determining program comprising:
instructions for transmitting a data packet to the slave through a serial data line after a predetermined delay time;
instructions for judging whether the transmitted data packet is received;
instructions for increasing the delay time by a predetermined increment of time and repeating the transmitting of the data packet, if the judging determines that the data packet is not received; and
instructions for determining the delay time as an optimal delay time between data packet transmissions from the master to the slave, if the judging determines that the data packet is received.

11. The storage medium of claim 10, wherein:
the slave is a storable memory, and the predetermined delay time is initialized to a value smaller than a write cycle timing of the memory.

12. The storage medium of claim 11, wherein the memory is an Electrically Erasable and Programmable Read Only Memory (EEPROM).

13. The storage medium of claim 10, wherein the serial data line is an inter-integrated circuit (IIC) bus data line.

14. A method of determining an optimal delay time between transmission of data packets in a system including a master and a slave connected through a serial data line, the method comprising:
transmitting a data packet from the master to the slave through the serial data line;
judging whether the transmitted data packet is received by the slave within a first delay time based on an acknowledge signal received from the slave; and
if the acknowledge signal is not received by the master within the first delay time,
repeating the transmitting of the data packet,
increasing the delay time by an increment to a second delay time,
judging whether the acknowledge signal is received from the slave within the second delay time, and
determining the second delay time to be an optimal delay time if the acknowledge signal is received within the second delay time.

15. The method of claim 14, wherein:
if the acknowledge signal is received by the master within the first delay time, determining the first delay time to be the optimal delay time.

16. A method of determining an optimal delay time between transmission of data packets in a system including a master and a slave, the method comprising:
transmitting a data packet from the master to the slave, the data packet comprising data to be stored, an address of the slave, and an address where the data is to be stored;
judging whether the transmitted data packet is correctly received by the slave within a first delay time based on a plurality of acknowledge signals regarding respective portions of the data packet received from the slave by the master; and
if at least one of the plurality of acknowledge signals is not received by the master within the first delay time, the judging determines that the data packet was not correctly received by the slave and the method further comprises:
increasing the first delay time by an increment to a second delay time,
repeating the transmitting of the data packet, and
judging whether the plurality of acknowledge signals regarding the respective portions of the retransmitted data packet are received within the second delay time.

17. The method of claim 16, wherein:
a first of the plurality of acknowledge signals corresponds to the data to be stored,
a second of the plurality of acknowledge signals corresponds to the address of the slave, and
a third of the acknowledge signals corresponds to the address where the data is to be stored.

18. The method of claim 17, further comprising:
determining the first delay time to be the optimal delay time between transmission of data packets, if all of the plurality of acknowledge signals are received within the first delay time.

19. The method of claim 17, further comprising:
determining the second delay time to be the optimal delay time between transmission of data packets, if all of the plurality of acknowledge signals are received within the second delay time.
